(19) United States
(12) Patent Application Publication
(10) Pub. No.: US 2005/0260503 A1
(43) Pub. Date: Nov. 24, 2005

(54) Reticle film stabilizing method

(75) Inventors: Wei-Lian Lin, Hsinchu City (TW); Chun-Hung Kung, Hsinchu City (TW); Chia-Hsien Chen, Puli Town (TW); Shan-Chan Shuc, Toufen Township (TW); Chian-Hun Lai, Taichung City (TW); Shao-Chi Wei, Taichung City (TW); Chi-Kang Chang, Rueitang Township (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/851,042

(22) Filed: May 20, 2004

(51) Int. Cl. G03F 9/00; G03C 5/00

(52) U.S. Cl. 430/5; 430/322; 430/323; 430/324

(57) ABSTRACT

A reticle film stabilizing method which is suitable for stabilizing a reticle film on a reticle, is disclosed. The method includes subjecting the multilayer reticle film to VUV (vacuum ultraviolet) radiation prior to the megasonic cleaning process. The method increases the oxygen content of the reticle film, resulting in an oxygen-rich film surface which protects the reticle film from peeling during cleaning. Furthermore, the method enhances the surface wettability of the reticle film in a megasonic cleaning tank, thereby enhancing the cleaning efficacy.

### FIELD OF THE INVENTION

The present invention relates to masks or reticles used to form integrated circuit patterns in a photoresist layer on a semiconductor wafer substrate. More particularly, the present invention relates to a reticle film stabilizing method which includes treatment of a typically molybdenum reticle film with ultraviolet radiation prior to cleaning of a reticle in order to prevent or reduce peeling of the film during cleaning.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

Photoresist materials are coated onto the surface of a wafer by dispensing a photoresist fluid typically on the center of the wafer as the wafer rotates at high speeds within a stationary bowl or coater cup. The coater cup catches excess fluids and particles ejected from the rotating wafer during application of the photoresist. The photoresist fluid dispensed onto the center of the wafer is spread outwardly toward the edges of the wafer by surface tension generated by the centrifugal force of the rotating wafer. This facilitates uniform application of the liquid photoresist on the entire surface of the wafer.

Spin coating of photoresist on wafers is carried out in an automated track system using wafer handling equipment which transport the wafers between the various photolithography operation stations, such as vapor prime resist spin coat, develop, baking and chilling stations. Robotic handling of the wafers minimizes particle generation and wafer damage. Automated wafer tracks enable various processing operations to be carried out simultaneously. Two types of automated track systems widely used in the industry are the TEL (Tokyo Electron Limited) track and the SVG (Silicon Valley Group) track.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

During the photolithography step of semiconductor production, light energy is applied through a reticle mask onto the photoresist material previously deposited on the wafer to define circuit patterns which will be etched in a subsequent processing step to define the circuits on the wafer. Because these circuit patterns on the photoresist represent a two-dimensional configuration of the circuit to be fabricated on the wafer, minimization of particle generation and uniform application of the photoresist material to the wafer are very important. By minimizing or eliminating particle generation during photoresist application, the resolution of the circuit patterns, as well as circuit pattern density, is increased.

As critical dimensions in IC fabrication decrease to feature sizes of 0.15 μm and less, light diffraction and scattering effects hinder the precise transfer of the circuit pattern from the reticle to the wafer. Therefore, optical enhancement techniques have been developed to improve the quality and definition of the circuit pattern image on the wafer. This area of optical lithography, known as subwavelength lithography, enables circuit patterns to be transferred to a wafer with a resolution that is slightly below the ligth exposure wavelength.

One type of subwavelength lithography mask which has been recently developed is the phase-shift mask (PSM). The PSM mask was developed to rectify imaging problems caused by light diffraction through small openings in the reticle. A PSM reticle includes a phase shifter surface having alternating light-transmitting regions which cause the light to be phase-shifted 180 degrees. The light-transmitting regions are out of phase with each other, such that light diffracted from opaque areas on the shifter surface encounters destructive interference with light diffracted from the light-transmitting regions. Consequently, the image contrast of the circuit pattern image transmitted through the light-transmitting regions onto the wafer is significantly enhanced.

A cross-sectional view of a PSM reticle 10 is shown in FIG. 1 and includes a transparent substrate 12, which is typically a low-thermal expansion material (LTEM) material such as quartz or glass. The substrate 12 includes a phase shifter surface 14 having multiple light-transmitting regions 16 and opaque regions 18. A patterned reticle film 20, which is typically molybdenum (Mo) and silicon (Si), is deposited on the substrate 12.

In use, ultraviolet radiation is transmitted through the substrate 12 and light-transmitting regions 16 onto a photoresist layer (not shown) on a substrate. Light diffracted into the opaque regions 18 encounters destructive interference with light diffracted from the light-transmitting regions 16. Consequently, the image contrast for the circuit pattern image on the photoresist layer on a wafer is substantially enhanced.

Reticles must remain meticulously clean for the creation of perfect images during its many exposures to pattern a circuit pattern on a substrate. Because the reticle film 20 is delicate and therefore vulnerable to damage, specialized cleaning processes have been developed to remove particles from the reticle 10. Typically, the reticle 10 is subjected to a megasonic cleaning process in a cleaning fluid such as ammonia, which is contained in a megasonic cleaning tank. High-frequency sound waves travel through the cleaning fluid to obliterate the particles on the reticle 10. However, the megasonic cleaning process frequently induces peeling of the reticle film 20, thereby inducing defects into circuit pattern images transmitted from the reticle 10 onto a photoresist layer on a wafer.

One solution to peeling of the reticle film 20 during the megasonic cleaning process has included reduction of the megasonic cleaning power. While it reduces peeling of the reticle film 20, however, the reduced-power megasonic cleaning process still leaves a residue of particulate contaminants on the reticle 10, due to incomplete obliteration of the particles. Therefore, a method is needed for stabilizing a Mo—Si reticle film on a PSM reticle to prevent or at least substantially reduce peeling of the film during a megasonic cleaning process.

An object of the present invention is to provide a method which is suitable for stabilizing a reticle film on a reticle to prevent or reduce peeling of the film during reticle cleaning.

Another object of the present invention is to provide a method which is suitable for stabilizing a molybdenum-silicon reticle film on a reticle to prevent or reduce peeling of the film during reticle cleaning.

Still another object of the present invention is to provide a novel method which is suitable for stabilizing a Mo—Si reticle film on a reticle by subjecting the film to VUV (vacuum ultraviolet) radiation prior to cleaning of the reticle.

Yet another object of the present invention is to provide a novel reticle film stabilizing method which is suitable for increasing the oxygen content in a Mo—Si reticle film on a reticle to prevent or at least reduce peeling of the film and transfer of peeling-induced defects from the reticle onto a wafer.

A still further object of the present invention is to provide a novel reticle film stabilizing method which is effective in stabilizing the phase shifting and transmission capabilities of a reticle during a photolithography process.

Yet another object of the present invention is to provide a novel method which is applicable to PSM (phase shift mask) reticles having a molybdenum-silicon reticle film thereon.

### SUMMARY OF THE INVENTION

In accordance with these and other objects and advantages, the present invention is generally directed to a novel reticle film stabilizing method which is suitable for stabilizing a typically Mo—Si reticle film on a reticle to prevent or at least miminize peeling of the layer during a megasonic reticle cleaning process. The method includes subjecting the multilayer reticle film to VUV (vacuum ultraviolet) radiation prior to the megasonic cleaning process. The method increases the oxygen content of the reticle film, resulting in an oxygen-rich film surface which protects the reticle film from peeling during cleaning. Furthermore, the method enhances the surface wettability of the reticle film in a megasonic cleaning tank, thereby enhancing the cleaning efficacy.

According to one embodiment of the invention, a newly-fabricated or previously used and cleaned PSM reticle having a Mo—Si reticle film is provided. The reticle is then subjected to VUV radiation to stabilize the reticle film by increasing the oxygen content of the film. Next, the reticle is used in a photolithography process to transfer a circuit pattern from the reticle to a photoresist layer on a wafer. The reticle is then subjected to a megasonic cleaning process to remove particles which remain on the reticle as a result of the photolithography process. The stabilized reticle film is resistant to peeling during reticle cleaning.

According to another embodiment of the invention, a PSM reticle which was used in an immediately prior photolithography step to transfer a circuit pattern onto a photoresist layer is provided. As a result of the photolithography process, the reticle is contaminated with particles that must be removed from the reticle prior to further use. Accordingly, the reticle is subjected to the VUV radiation exposure step in order to stabilize the reticle film for subsequent megasonic cleaning. After the VUV radiation exposure step, the reticle is subjected to megasonic cleaning to obliterate particles which remain on the film after the photolithography process.

### BRIEF DESCRIPTION OF THE DRAWING

The invention will now be described, by way of example, with reference to the accompanying drawing, in which:

FIG. 1 is a cross-section of a typical conventional PSM (phase shift mask) reticle; and

FIG. 2 is a flow diagram which summarizes sequential process steps according to the method of the present invention.

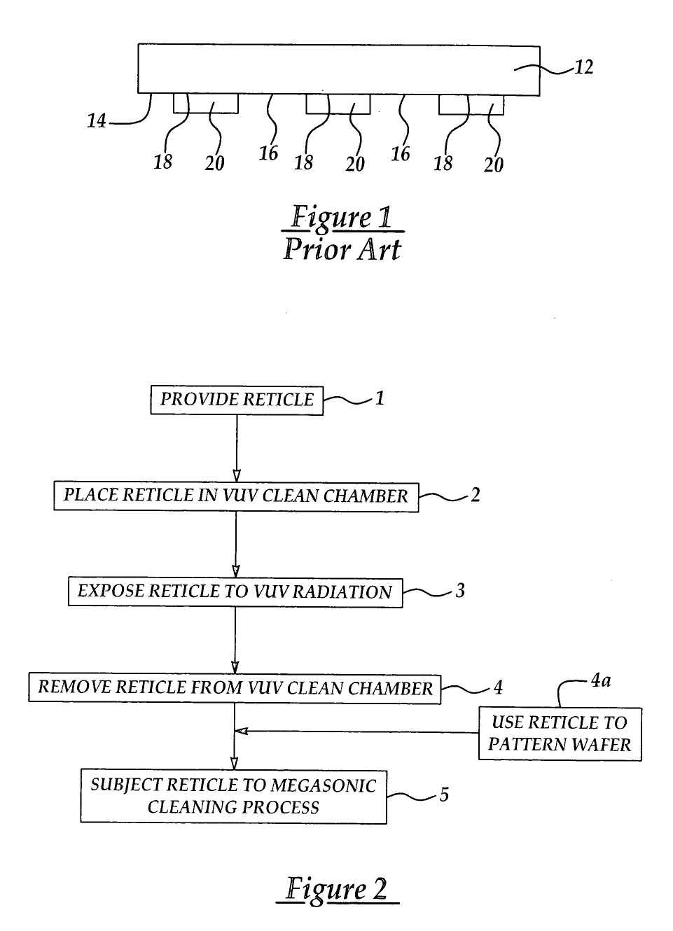

### DETAILED DESCRIPTION OF THE INVENTION

The present invention contemplates a novel reticle film stabilizing method which is suitable for stabilizing a typically Mo—Si reticle film on a PSM (phase shift mask) reticle to prevent or minimize peeling of the film during a megasonic reticle cleaning process. The method is also capable of enhancing the surface wettability of the film to increase the efficacy of the cleaning process, and effectively stabilizes the phase shift and transmission capability of the reticle in subsequent photolithography applications. According to the method, the reticle film is subjected to VUV (vacuum ultraviolet) radiation prior to megasonic cleaning of the reticle. The VUV radiation increases the oxygen content of the reticle film, resulting in an oxygen-rich reticle film surface which renders the reticle film substantially resistant to peeling during cleaning.

As the reticle film is subjected to the VUV radiation, oxygen free radicals are generated above the film. It is believed that the oxygen free radicals combine with the typically MoSiON reticle film, creating an oxygen-rich surface on the film. A key factor may involve the conversion of organosilicon in the film to silicon oxide. This enhances the reticle film stability and renders the reticle film substantially resistant to peeling during a subsequent megasonic cleaning process.

According to the method of the invention, a PSM (phase shift mask) reticle having a molybdenum-silicon reticle film is provided. The PSM reticle may be a newly-fabricated reticle, a previously-used and cleaned reticle, or a reticle which was used in an immediately-prior photolithography process to transfer a circuit pattern onto a photoresist layer on a wafer. The reticle is then placed in a VUV radiation clean chamber and subjected to VUV light which is typically in the 170 nm-200 nm wavelength range. This step stabilizes the reticle film preparatory to the subsequent megasonic cleaning step, by increasing the oxygen content of the film.

After it is removed from the VUV clean chamber, the reticle may then be used in a photolithography process (in the case of a newly-fabricated or previously-used and cleaned reticle) to transfer an IC circuit pattern to a photolithography layer on a wafer, and then subjected to megasonic cleaning to remove particles from the reticle. In the event that the reticle is a previously-used reticle in which the photolithography step was carried out immediately prior to the VUV radiation-exposure step, the reticle may be subjected to megasonic cleaning immediately after the VUV radiation-exposure step.

The VUV-exposure step may be carried out, for example, in a Usio VUV clean chamber which is available from Ushio Electric Co., Ltd. The reticle is placed in the chamber and subjected to VUV radiation having a wavelength of typically about 170˜200 nm for an exposure time period of typically at least about 1 hour and at a power of typically about 300˜500 watts. Preferably, the reticle is exposed to VUV radiation having a wavelength of typically about 172 nm for an exposure time of typically about 4 hours.

The megasonic cleaning process may directly follow the VUV radiation-exposure step (in the event that the reticle was used in a photolithography process prior to VUV exposure), or alternatively, may follow a post-exposure photolithography process in which the reticle is used to transfer a circuit pattern to a photoresist layer on a wafer. The megasonic cleaning process may be carried out in a conventional megasonic cleaning apparatus, typically using an SC-1 cleaning solution that contains ammonium hydroxide, hydrogen peroxide and DI (deionized) water, according to the knowledge of those skilled in the art.

According to such a process, the reticle is immersed in the SC-1 cleaning solution and subjected to megasonic cleaning at a megasonic power of typically about 100˜350 W for a cleaning period of typically about 260˜300 sec. The megasonic waves generated in the cleaning solution obliterate particles which remain on the reticle as a result of the photolithography process. As they are dislodged from the reticle, the obliterated particles are dissolved in the cleaning solution. The reticle is then removed from the cleaning solution for subsequent use in another photolithography process.

It will be appreciated by those skilled in the art that the reticle film stabilizing method of the present invention is capable of stabilizing the reticle film on a PSM reticle such that cleaning-induced peeling of the reticle film is substantially reduced. It has been found, for example, that exposure of the reticle film to 172 nm VUV radiation for an exposure time of 4 hours, followed by megasonic cleaning at a power of 100 W, is capable of reducing the incidence of peeling-related defects from 263 to 24.

Referring next to FIG. 2, a flow diagram which summarizes sequential process steps according to the method of the present invention is shown. In process step 1, a PSM reticle having a typically molybdenum-silicon reticle film thereon is provided. The PSM reticle may be a newly-fabricated or previously-used and cleaned reticle, or alternatively, may be a reticle which was used in a photolithography process immediately prior to process step 1. In process step 2, the reticle is placed in a VUV radiation clean chamber, such as, for example, a Usio VUV radiation clean chamber available from Ushio Electric Co., Ltd. In process step 3, the reticle is exposed to VUV radiation to stabilize the reticle film by increasing the oxygen content of the film. In process step 4, the reticle is removed from the VUV radiation clean chamber.

In the event that the reticle is a previously-used reticle which was used in a photolithography step carried out immediately prior to process step 1, the reticle is then subjected to a megasonic cleaning process to remove particles from the reticle, as indicated in process step 5. Alternatively, in the event that the reticle was cleaned or fabricated prior to process step 1, the reticle is used in a photolithography process to transfer a circuit pattern to a wafer, as indicated in process step 4a. Following photolithography, the reticle is subjected to the megasonic cleaning process to remove the particles from the reticle, as indicated in process step 5.

While the preferred embodiments of the invention have been described above, it will be recognized and understood that various modifications can be made in the invention and the appended claims are intended to cover all such modifications which may fall within the spirit and scope of the invention.

1. A method of stabilizing a reticle film on a reticle, comprising:
providing a reticle having a reticle film; and
increasing an oxygen content of said reticle film by subjecting said reticle film to ultraviolet radiation.

2. The method of claim 1 wherein said reticle film comprises molybdenum.

3. The method of claim 1 wherein said ultraviolet radiation has a wavelength of from about 170 nm to about 200 nm.

4. The method of claim 3 wherein said reticle film comprises molybdenum.

5. The method of claim 1 further comprising the step of subjecting said reticle to a megasonic cleaning process.

6. The method of claim 5 wherein said reticle film comprises molybdenum.

7. The method of claim 5 wherein said ultraviolet radiation has a wavelength of from about 170 nm to about 200 nm.

8. The method of claim 7 wherein said reticle film comprises molybdenum.

9. A method of stabilizing a reticle film on a reticle, comprising:
providing a reticle having a reticle film; and
increasing an oxygen content of said reticle film by subjecting said reticle film to ultraviolet radiation having a wavelength of from about 170 nm to about 200 nm for an exposure period of at least about 1 hour.

10. The method of claim 9 wherein said reticle film comprises molybdenum.

11. The method of claim 9 further comprising the step of subjecting said reticle to a megasonic cleaning process.

12. The method of claim 11 wherein said reticle film comprises molybdenum.

13. The method of claim 9 wherein said wavelength is about 172 nm.

14. The method of claim 13 wherein said reticle film comprises molybdenum.

15. The method of claim 13 further comprising the step of subjecting said reticle to a megasonic cleaning process.

16. The method of claim 15 wherein said reticle film comprises molybdenum.

17. A method of stabilizing a reticle film on a reticle, comprising:
providing a reticle having a reticle film; and
increasing an oxygen content of said reticle film by subjecting said reticle film to ultraviolet radiation having a wavelength of from about 170 nm to about 200 nm for an exposure period of about 4 hours.

18. The method of claim 17 wherein said wavelength is about 172 nm.

19. The method of claim 18 further comprising the step of subjecting said reticle to a megasonic cleaning process.

20. The method of claim 19 wherein said reticle film comprises molybdenum.
